(19) United States
(12) Patent Application Publication
(10) Pub. No.: US 2007/0144578 A1
(43) Pub. Date: Jun. 28, 2007

(54) Means and Method for Electrically Connecting Photovoltaic Cells in a Solar Module

(75) Inventors: Daniel W. Cunningham, Mount Airy, MD (US); Joseph B. Creager, Libertytown, MD (US); John H. Wohlgemuth, Ijamsville, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP CORPORATION NORTH AMERICA INC., Warrenville, IL (US)

(21) Appl. No.: 11/563,410

(22) Filed: Nov. 27, 2006

Related U.S. Application Data
(60) Provisional application No. 60/758,519, filed on Jan. 12, 2006.
(60) Provisional application No. 60/741,916, filed on Dec. 2, 2005.

(51) Int. Cl. H01L 31/00

(52) U.S. Cl. 136/256

(57) ABSTRACT

A connector and method for electrically connecting adjacent solar cells together in a solar module. The terminals of the cells are connected with individual lengths of an electrically conductive material such as an electrically conductive metal ribbon. A substantial portion of the mid section of the ribbons remain unsoldered to thereby provide a stress relief zone in the ribbon between the cells to alleviate stress failures in the ribbons.

This application claims the benefit of U.S. Provisional Patent Application 60/741,916 filed on Dec. 2, 2005, and 60/758,519 filed on Jan. 12, 2006.

### FIELD OF THE INVENTION

The present invention relates to electrically connecting photovoltaic (PV) cells within a solar module and in one of its aspects relates to a means and method for electrically connecting a plurality of PV cells in a solar module to effectively extend the operational life of the connections between PV cells.

### BACKGROUND OF THE INVENTION

In recent years, considerable advances have been made in photovoltaic cells or the like for directly converting solar energy into useful electrical energy. Typically, a plurality of these photovoltaic cells are encased between a transparent sheet (e.g. glass, plastic, etc.) and a sheet of backing material to thereby form a flat, rectangular-shaped module (sometimes also called “laminate” or “panel”) of a manageable size (e.g. 2½′×5′). This is the type of solar module which is usually installed onto the roof of an existing structure (e.g. a house, building, or the like) to provide all or at least a portion of the electrical energy used by that structure.

One major consideration in the construction of such solar modules is how the individual PV cells are electrically connected within the module. Typically, the PV cells are positioned in a plurality of rows in close proximity and are electrically connected in series with the positive side (i.e. terminal or output) of one cell being connected to the negative side (i.e. input) of an adjacent PV cell. The cells are connected by lengths of an electrically conductive material (e.g. wires or flat ribbons of copper, aluminum, etc. and hereinafter referred to as “ribbon”) having ends which are soldered to the appropriate sides of the respective cells.

Typically, each end of each ribbon is soldered to the top or bottom of its respective PV cell for a portion of its length and substantially up to or very near the edge of the respective PV cells. That is, the majority of the ribbon is soldered to the cells with only the short length which actually lies between the adjacent cells being unsoldered.

While these connections appear to work well over relatively long periods, it has been found that some of these connections may fail before the expected useful life of the solar modules has ended. It appears that a major reason that one or more of these connections may fail results from the stress which is experienced by the short length of the ribbon between the cells as it expands and contracts caused by the cyclic changes in temperature over the operational life of the module. This stress fatigues the ribbon and causes it to break much like the continuous flexing of a wire leads to the wire breaking at the point of flexure and can cause failure of the solder joint, itself.

Since the solar modules are sealed units, the failure of only one of these connections between PV cells (which are usually connected in series) can render a module inoperable and require replacement long before its otherwise useful life is over. Due to the costs involved, this can seriously detract from the commercialization of solar power. Accordingly, it can be seen that any extension in the life of the electrical connectors in a particular solar module can, in turn, extend the operational life of that solar module and will thereby provide a significant benefit to the users of the solar modules.

### SUMMARY OF THE INVENTION

The present invention provides a means and method for electrically connecting adjacent PV cells together in a solar module. Basically, the terminals of adjacent cells are connected together using individual lengths of an electrically conductive material; e.g. lengths of ribbons made of copper or the like which are typically coated with solder. A substantial portion of the mid section of electrically conductive material, such as the ribbons, remains unsoldered to thereby provide a stress relief zone in the electrically conductive material between the cells to alleviate stress failures in the ribbons. The PV cells can be, and preferably are, of the type made from semiconductor wafers, such as silicon wafers. The silicon wafers can be made from mono-crystalline or multi-crystalline silicon. These PV cells can be any shape, but are typically circular, square, rectangular or pseudo-square in shape. By “pseudo-square” is meant a predominantly square shape usually with rounded corners. For example, a mono-crystalline or multi-crystalline PV cell useful in this invention can be about 50 microns thick to about 400 microns thick. If circular, it can have a diameter of about 100 to about 200 millimeters. If rectangular, square or pseudo square, it can have sides of about 100 millimeters to about 210 millimeters and where, for the pseudo-square wafers, the rounded corners can have a diameter of about 127 to about 178 millimeters. Such wafers and cells and methods for making them are known in the art.

More specifically, the present invention provides a connector for electrically connecting two adjacent PV cells. Each cell has a negative terminal thereon and a positive terminal thereon. The terminals can be on the same or opposite sides of the PV cell. The connector or ribbon spans the gap between the two adjacent cells and has a first end in contact with a terminal of one cell and a second end in contact with a terminal of an adjacent cell. If the cells are to be connected in series, then a positive terminal of one cell is connected to a negative terminal on an adjacent cell while terminals of like polarities (i.e. positive-to-positive and negative-to-negative) will be connected if the cells are to be connected in parallel. In any event, only a portion of each end of the ribbon is soldered to its respective terminal so that a substantial portion of the midsection of the ribbon remains unsoldered to thereby form a stress relief zone in the ribbon between the respective said cells.

The length of ribbon that is to remain unsoldered will depend on the particular situation involved, e.g. different cell, etc. Basically, however, this length should be equal to the distance across the gap between the adjacent cells plus a distance on either side of the gap which is equal to about at least 4 times that of the distance across said gap.

### BRIEF DESCRIPTION OF THE DRAWINGS

The actual construction operation, and apparent advantages of the present invention will be better understood by referring to the drawings, not necessarily to scale, in which like numerals identify like parts and in which:

FIG. 1 is a perspective view of an array of solar modules constructed in accordance with an embodiment the present invention installed onto a roof of a house or the like;

FIG. 2 is a top view of a typical solar module of the type shown in FIG. 1 having a portion of its top surface broken away to show the individual PV cells;

FIG. 3 is a top view of a simplified embodiment of the module of FIG. 2 illustrating an embodiment of the connectors of the present invention for electrically connecting the PV cells of the module of FIG. 2;

FIG. 4 is top view of two adjacent PV cells further showing the electrical connections of an embodiment of the present invention;

FIG. 5 is a slightly enlarged side view of FIG. 4; and

FIG. 6 is an enlarged section taken within line 6 in FIG. 5.

While the invention will be described in connection with its preferred embodiments, it will be understood that this invention is not limited thereto. On the contrary, the invention is intended to cover all alternatives, modifications, and equivalents that may be included within the spirit and scope of the invention, as defined by the appended claims.

### DETAILED DESCRIPTION OF THE INVENTION

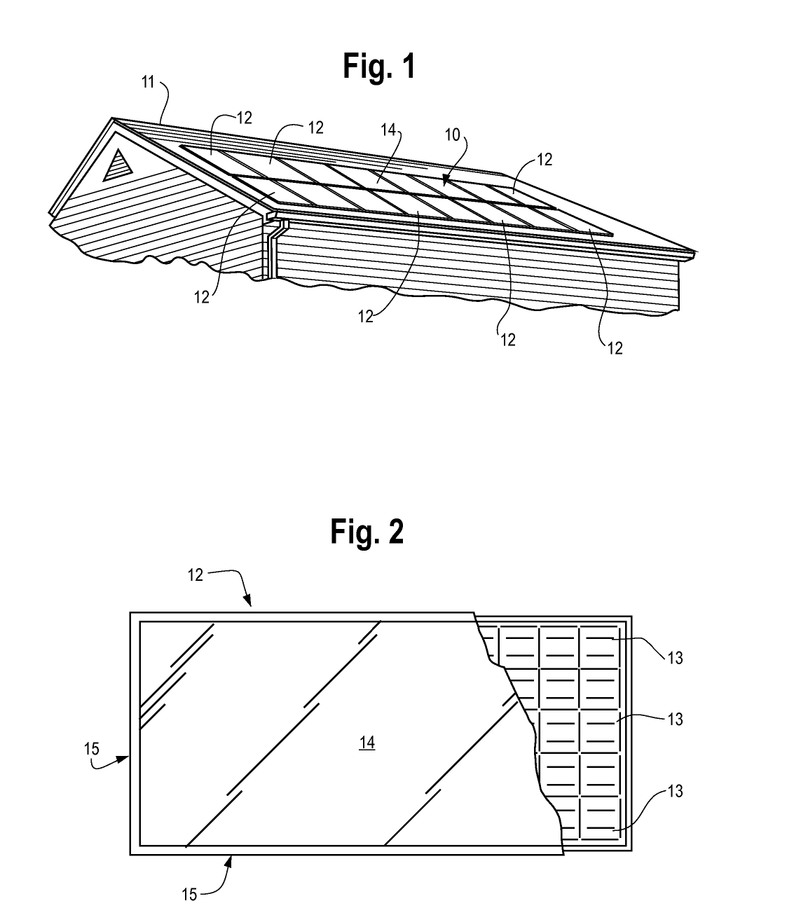

Referring now to the drawings, FIG. 1 illustrates a typical solar array 10 incorporating the present invention which has been mounted on a support surface (e.g. roof 11 of a house or the like). Array 10 is comprised of a plurality (sixteen shown) of solar modules 12 (only some numbered) which have been secured to the roof 11 as shown. As will be fully understood in the art, a typical solar module 12 is basically formed by positioning a plurality of photovoltaic (PV) cells 13 (FIG. 2) between a sheet of a transparent material 14 (e.g. glass, plastic, etc.) and another sheet of material (not shown), whereby the finished module 12 is effectively a flat, rectangular, plate-like structure as shown in the figures.

To complete the assembly of module 12, the sandwich of PV cells 13 is typically encased within a frame 15. Typical measurements of a solar cell module 12 of this type is approximately thirty-one (31) inches wide and sixty-three (63) inches long. A suitable frame for a module is described in, for example, U.S. Pat. No. 6,111,189 and U.S. Pat. No. 6,465,724 B1, both of which are incorporated by reference herein in their entireties.

In assembling module 12, it is necessary to electrically connect the PV cells 13 together. Usually, the cells are connected in series, i.e. the positive/negative terminal(s) of one cell is electrically connected to the opposite respective negative/positive terminals) of an adjacent cell and so on. In some situations, however, it may be desirable to connect the cells in parallel, i.e. the terminals of like polarity (positive-to-positive or negative-to-negative) are connected of adjacent cells are electrically connected. Typically, these cells have been connected with relatively short lengths of conductive wire or more recently with flat strips of a thin, conductive material, hereinafter called “ribbon”.

In order to generate the maximum amount of electrical energy in the space available, it is desirable to fit as many PV cells as possible into each individual module 12. It follows that the cells are usually positioned as close to each other as conditions allow. By using preferred ribbon connectors, the PV cells can be placed in very close proximity of each other (i.e. the ends of adjacent cells being almost in abutment with each other). Each strip of ribbon connector has one end soldered to a terminal (top/bottom surface) of a respective cell and its other end soldered to a terminal (bottom/top surface) of an adjacent cell.

In known prior art solar modules of this type, the ribbon strips are soldered to the respective surfaces along a substantial portion of their entire lengths and the solder continues to a point substantially adjacent the respective edges of the connected, adjacent cells. This leaves only a very short length of ribbon between modules that is free to expand and contract in response to alternating changes in temperature which frequently occur during the operational life of a solar module. Unfortunately, this expansion and contraction fatigues the metal connector whereby the connector may break before the usual life of the module has been realized.

If and when only one connector breaks, the efficiency of the module can be severely compromised and, depending on the wiring pattern within the module, the module may become totally inoperable. Since the PV cells are sealed in the module during assembly, it is not practical to try and repair a broken connection if one should occur. Therefore, if a connection should break during the operational life of a module, the only realistic repair is to replace the entire module that, in turn, is obviously expensive to the user.

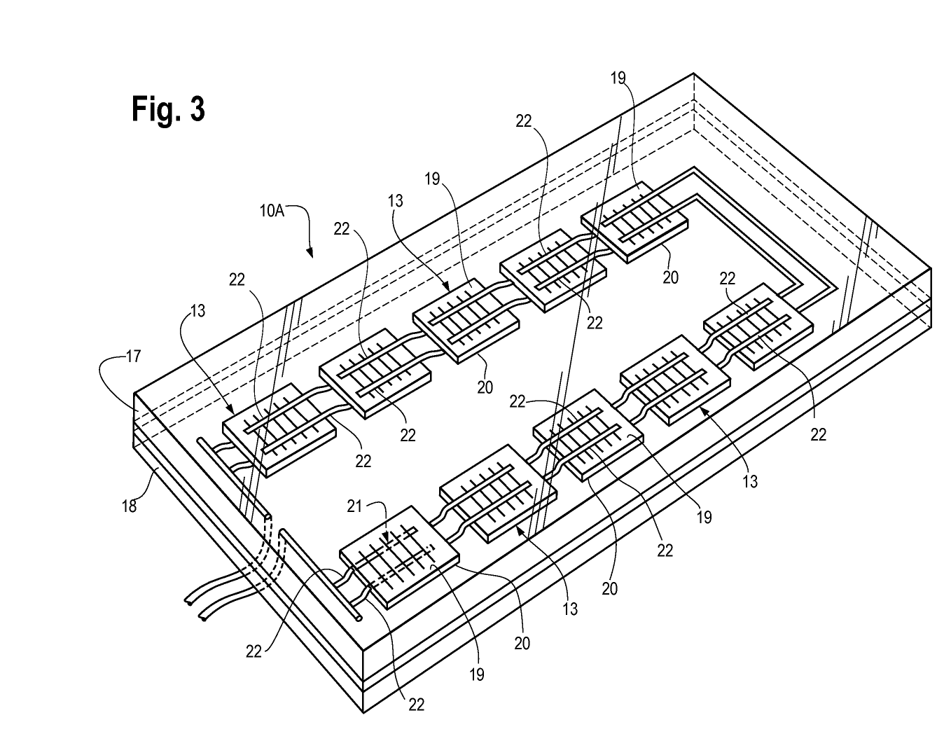

The present invention provides an electrical connection between adjacent PV cells in a module which are less susceptible to fatigue and therefore less likely to fail during the normal operational life of a typical solar module. Referring again to the drawings, FIGS. 3-6 illustrate the electrical connection in accordance with one embodiment of the present invention. The simplified solar module 10A of FIG. 3 is shown having two rows of five PV cells 13 (only some numbered for clarity) which are sealed between transparent sheet 17 (e.g. glass, plastic, etc.) and a sheet of backing material 18.

Before the PV cells are sealed within the modules, they must be electrically connected. Typically, the cells are connected in series, e.g. positive terminal(s) of one cell to the negative terminal(s) of an adjacent cell. Each PV cell 13 usually has one side or surface which includes a electrical terminal(s) and one side or surface which is includes an opposite electrical terminal(s). As shown, the upper surface 19 includes one terminal (e.g. positive) when the module is in an operable position and the lower surface 20 includes the opposite terminal (e.g. negative) but it should be realized that the upper side 19 can include the negative terminal and the lower side 20 can include the positive terminal without departing from the present invention. “Positive” and “negative” are used herein only as relative terms to identify the opposite electrical polarities of a cell.

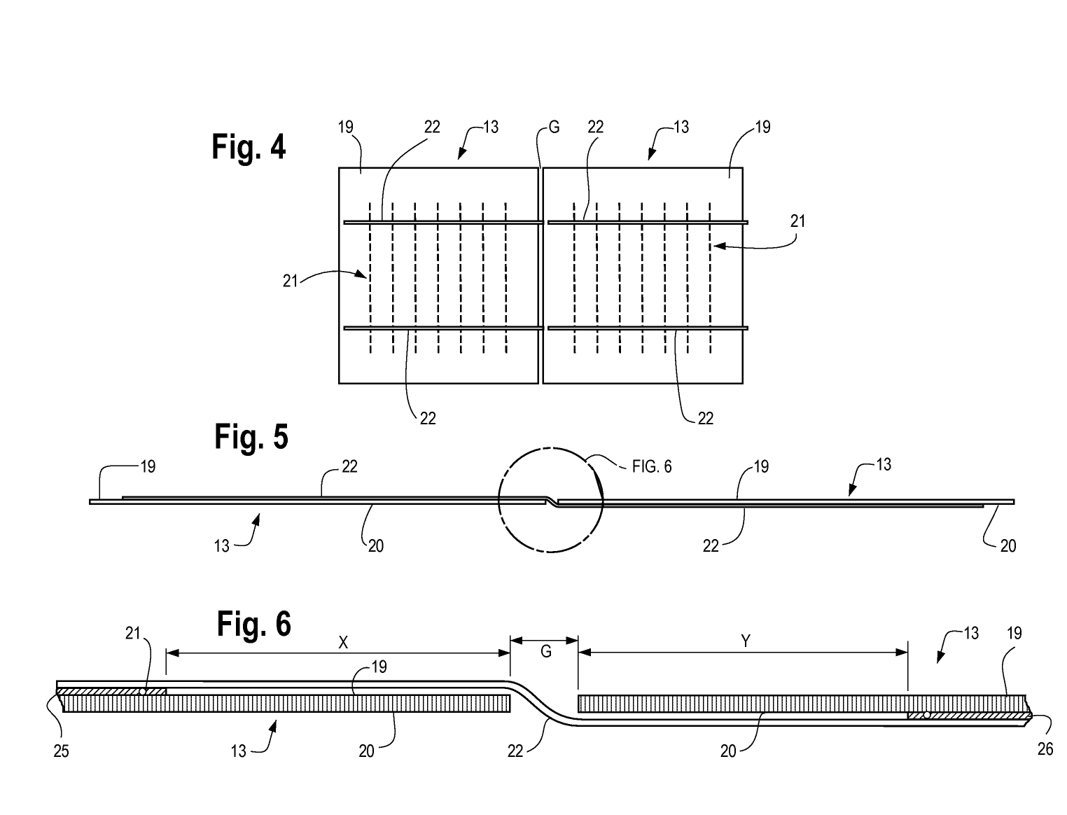

As will be understood in the art, both the top and bottom of each PV cell 13 may be fabricated to have a bus, busbar, pad(s), and/or grid 21 (FIGS. 3 and 4) comprised of an electrically conductive solderable material (e.g. copper, aluminum, alloys, etc.) which provides the respective negative/positive terminals for the cell. For example, the lower side of cell 13 can have four spaced terminals or pads (not shown) on a screen printed surface. Since the upper surface 19 of the cell is the one that is exposed to the sun, the terminal (e.g. grid 21) preferably blocks as little of the surface as possible to permit the maximum amount of sunlight exposure to the cell's surface. A grid pattern is usually used for such electrical terminals on the surface of the cell that is exposed to the sun. In some cells, however, both terminals may be on the back or bottom of the cell.

Now, the electrical connections in accordance with the present invention will be described. As shown, individual strips or ribbons 22 of a conductive material are used to connect adjacent PV cells 13 in series. Ribbons 22 can be of any appropriate conductive material (e.g. flat ribbons of copper, aluminum, or an alloy or laminate of conductive material such as copper, aluminum, invar, tin, or lead; any of which are preferably coated with an electrically conductive solder such as silver). As shown, each connection between adjacent PV cells 13 is comprised of two individual strips of ribbon 22 but it should be realized that only one strip can be used or more than two strips can be used to form these connections depending on a particular situation, e.g. cell size, etc.

As in the prior art, one end of a ribbon 22 is soldered to a terminal (negative or positive) on one side (e.g. top surface) of a particular cell 13 and the other end of that same ribbon is soldered to an opposite terminal (positive or negative) on the other side (e.g. bottom surface). However, in accordance with the present invention, in addition to that portion of the ribbon which spans the gap G (FIGS. 4 and 6) between cells, a substantial length (X,Y FIG. 6) of the ribbon 22 on either side of the gap G is also left unsoldered. That is, a first batch of solder 25 which solders one end of the ribbon 22 to the terminal on the top surface of one cell does not extend to the edge of the cell but terminates at a significant distance X therefrom. Likewise a second batch of solder 26 which solders the other end of ribbon 22 to the terminal on the bottom surface of the adjacent cell does not begin at the edge thereof but starts at a significant distance Y therefrom.

While the actual distance between the respective batches of solder (i.e. the length of unsoldered ribbon (X+G+Y)) will vary depending on a particular situation (e.g. cell size), it has been found that the length of both X and Y should be at least about 4 times, for example at least about 4 times up to about 5 times, that of the length of the ribbon spanning gap G in order to provide the desired stress relief zone. That is, if the length of the ribbon across gap G is 2 mm, then the unsoldered lengths X and Y of ribbon 22 can be around about 10 mm each, or the total unsoldered length of ribbon 22 (i.e. stress relief zone) can be or can approximately be a total of 22 mm (10 mm+2 mm+10 mm). It should be realized that X and Y do not have to be equal to each other in length as long as the desired stress relief zone is provided when the ribbon is soldered.

The substantial length in the mid section of each ribbon 22 which is left unsoldered provides a stress relief zone preferably is not exposed to the heat, solder flux, or the physical contact of the heat source required in soldering the ribbon to its respective terminals. By so doing, several of the factors that can cause stress cracking of the ribbon or failure of the solder connections, themselves, is eliminated. Further, any fatigue caused by the expansion and/or contraction of the ribbon during operation will occur over a significantly greater length of the ribbon thereby alleviating excessive fatigue at a concentrated point on the ribbon within gap G which, in turn, could cause failure of the connection. It should be recognized that the length spanning the gap does not have to be taut but may include a loop or the like (not shown) as long as the stress relief zone is established between cells.

The following specific example of a typical solar module incorporating the present invention will be helpful in further understanding the present invention. As will be understood in the art, an array of seventy-two PV cells (not shown) are laid out on trays or in a robotic handling fixture in six rows of twelve cells each. A typical PV cell used in modules of this type is a high-efficiency silicon nitride mono-crystalline cell whose dimensions are 125 mm×125 mm. Individual lengths (e.g. approximately 230 mm long, 1.5 to 1.8 mm wide, and 100 to 260 microns thick) of electrically-conductive ribbon are positioned so that one end of a particular ribbon is in contact with the negative terminal on the top of one cell and the other end of that ribbon is in contact with the positive terminal on the bottom of an adjacent cell. Preferably, the ribbons are comprised of copper which is coated with silver solder.

Once the ribbons are in place, the ribbons are soldered to their respective surfaces by any appropriate means, preferably by a technique known in the industry as “touchless” soldering. In this technique, the heat for soldering is applied by an infrared lamp, flame, or hot air thereby minimizing the force normally encountered between the heat source and the ribbon during soldering techniques. As explained above, the stress relief zone of the ribbon (i.e. the length of ribbon which spans the gap between adjacent cells plus a length on either side of the gap equal to about 4 times the length across the gap) is not soldered to the PV cells.

In the present example of the present invention, the one end of ribbon 22 is soldered to its terminal but the solder is applied or the soldered-covered end of a soldered covered ribbon is heated and attached so that this “first” batch of conductive solder 25 (FIG. 6)that connects the ribbon to the PV cell ends about 10 mm prior to reaching the leading edge of the first cell 13 as viewed in FIG. 6. The other end of the ribbon 22 is soldered to its respective terminal but, again, the solder is applied or the soldered-covered end of a soldered covered ribbon is heated and attached so that this “second” batch of solder 26 that connects the ribbon to the PV cell begins about 10 mm from the trailing edge of the adjacent cell. This unsoldered mid section of ribbon 22 provides a stress relief zone which is equal to about 22 mm (i.e. 10 mm+2 mm+10 mm).

After all the electrical connections between the PV cells have been made, the connected cells are positioned on a backing sheet of plastic or the like and a transparent (e.g. glass) sheet is laid onto the cells and the laminate is fused together by heat as will be understood in the art. The finished laminate is typically enclosed in a metal frame (see 15, FIG. 2) and is now ready for installation on a structure.

U.S. Provisional Patent Application 60/741,916, filed on Dec. 2, 2005, and 60/758,519, filed on Jan. 12, 2006, are each hereby incorporated by reference in their entirety.

What is claimed is:

1. A connector for electrically connecting two adjacent PV cells having a gap therebetween, each cell having a terminal, said connector comprising:
a length of an electrically conductive material having a first end and a second end, said first end in contact with said terminal of a first of said two PV cells and said second end in contact with said terminal of the second of said two PV cells whereby said length of conductive material spans across said gap between said cells;
a contact for electrically connecting said first end of said length of conductive material to said terminal of said first cell; and
a contact for electrically connecting said second end of said length of conductive material to said terminal of said second cell wherein said electrical contacts are spaced from each other whereby a significant mid portion of said length of conductive material forms a stress relief zone in said length of conductive material between the respective said cells.

2. The connector of claim 1 wherein said contacts are comprised of solder.

3. The connector of claim 2 wherein said length of electrical conductive material comprises:
a length of ribbon of electrical conductive material.

4. The connector of claim 3 wherein said ribbon is comprised of a laminate comprised of copper, aluminum, invar, tin, or lead coated with solder.

5. The connector of claim 3 wherein said unsoldered length of ribbon is equal to the distance across said gap plus a distance on either side of said gap which is equal to at least about 4 times that of said distance across said gap.

6. The connection of claim 5 wherein said gap is equal to about 2 mm and the unsoldered length of said ribbon is equal to about 22 mm.

7. The connection of claim 1 wherein said terminal of said first cell is positive and said terminal of said second cell is negative whereby said cells are connected in series.

8. The connection of claim 1 wherein said terminal of said first cell and said terminal of said second cell are of like polarities whereby said cells are connected in parallel.

9. A connector for electrically connecting two adjacent PV cells having a gap therebetween, each cell having a terminal thereon, said connector comprising:
a length of an electrical conductive material having a first end and a second end, said first end in contact with said terminal of the first of said two PV cells and said second end in contact with said terminal of the second of said two PV cells whereby said length of conductive material spans across said gap between said cells;
a first batch of solder electrically connecting said first end of said length of conductive material to said terminal of said first cell; and
a second batch of solder electrically connecting said second end of said length of conductive material to said terminal of said second cell wherein a significant portion of said length of conductive material is unsoldered to the PV cells thereby forming a stress relief zone in the mid section of said length of conductive material between said respective cells.

10. The connector of claim 9 wherein said length of electrical conductive material comprises:
a length of ribbon of electrical conductive material.

11. The connector of claim 10 wherein said unsoldered length of ribbon is equal to the distance across said gap plus a distance on either side of said gap which is equal to at least about 4 times that of said distance across said gap.

12. A solar module comprising:
a plurality of PV cells positioned in close proximity of each other, each cell having a terminal thereon,
a plurality of connectors for electrically connecting adjacent cells together, each connector comprising:
a length of an electrical conductive material having a first end and a second end, said first end extending across a portion of a first of said plurality of PV cells and in contact with said terminal thereon and said second end extending across a portion of a second of said plurality of PV cells and in contact with said terminal thereon whereby said length of conductive material extends along a portion of the respective said first and second adjacent PV cells and spans across said gap between said respective PV cells;
a first batch of solder electrically connecting said first end of said length of conductive material to said terminal of said first PV cell; and
a second batch of solder electrically connecting said second end of said length of conductive material to said terminal of said second adjacent PV cell, said first batch of solder and said second batch of solder being spaced from the edges of their respective adjacent cells whereby a significant length of said length of conductive material remains unsoldered along the mid section thereof thereby forming a stress relief zone in said connector between said first and second PV cells.

13. The solar module of claim 12 wherein said length of electrical conductive material comprises:
a length of ribbon of electrical conductive material.

14. The solar module of claim 13 wherein said ribbon is comprised of a laminate comprised of copper, aluminum, invar, tin, or lead coated with solder.

15. The connector of claim 13 wherein said unsoldered length of ribbon is equal to the distance across said gap plus a distance on either side of said gap which is equal to about at least 4 up to about 5 times said distance across said gap.

16. A method for electrically connecting two adjacent PV cells together, said method comprising:
placing said PV cells in close proximity to each other;
positioning a length of an electrically conductive material across the gap between said PV cells so that one end of said conductive material is in contact with a terminal of a first of said two PV cells and its other end is in contact with a terminal of the second of said two PV cells;
soldering a portion of a first end of said length of conductive material to said terminal of said first PV cell so that a substantial portion of said length of conductive material which extends from said soldered terminal to the edge of said first PV cell remains unsoldered; and
soldering a portion of a second end of said length of conductive material to said terminal of said second PV cell so that a substantial portion of said length of conductive material which extends from said soldered terminal to the edge of said second PV cell will remain unsoldered;
whereby said unsoldered portions of said length of conductive material and that portion of said length of conductive material that spans the gap between said two adjacent PV cells form a stress relief zone in said length of conductive material to alleviate stress failures in said length of conductive material.

17. The method of claim 16 wherein said length of conductive material comprises:
a length of ribbon made of an electrically conductive material.

18. The method of claim 17 wherein said ribbon is comprised of copper coated with solder.

19. The solar module of claim 17 wherein said ribbon is comprised of a laminate comprised of copper, aluminum, invar, tin, or lead coated with solder.

20. The method of claim 16 wherein said unsoldered length of electrical conductive material is equal to the distance across said gap plus a distance on either side of said gap which is equal to about at least 4 times said distance across said gap.

21. The method of claim 17 wherein more than one individual length of ribbon is used between two adjacent PV cells.
